(19) United States
(12) Patent Application Publication
(10) Pub. No.: US 2014/0226136 A1
(43) Pub. Date: Aug. 14, 2014

(54) METHOD AND APPARATUS FOR CLEANING PHOTOMASK HANDLING SURFACES

(71) Applicant: Patrick J. Gagnon, Richardson, TX (US)

(72) Inventor: Patrick J. Gagnon, Richardson, TX (US)

(21) Appl. No.: 13/764,196

(22) Filed: Feb. 11, 2013

(51) Int. Cl. G03F 1/82

(52) U.S. Cl. CPC G03F 1/82
USPC 355/30

(57) ABSTRACT

The cleaning device may clean the handling and support interface for a reticle inside a reticle handling tool, such as a micrographic scanner/stepper printer, without opening the tool. The cleaning device may have the same or approximate form factor as either a reticle without a pellicle or a reticle with a pellicle. The cleaning device is transported through the reticle handling tool in the same manner and along the same path as a reticle, contacted against surfaces that a reticle touches, and transferred out of the reticle handling tool. The cleaning device comprises a cleaning pad, secured to the base substrate, the cleaning pad having predetermined characteristics that cause the cleaning pad to remove contamination and particulates from the reticle transfer and placement equipment when the cleaning device contacts the robot transfer arm(s) and reticle positioning/support interface.

This nonprovisional utility patent application follows from U.S. Provisional Patent Application Filing No. 61/617,464 by Patrick J Gagnon of Semicon PhotoMetrology Solutions L.L.C. filed Mar. 29, 2012, the priority of which is hereby claimed.

### BACKGROUND OF THE INVENTION

Under current practice, reticle transfer and placement equipment, such as reticle handling and positioning/support interface components of a reticle handling tool, is used to load reticles into a tool, position reticles inside the tool, and remove reticles from the tool. As will be appreciated by a person skilled in the art, reticle handling tools include, for example, micrographic optical scanner/stepper printers, immersion scanners, deep ultraviolet (deep UV) and extreme ultraviolet (EUV) lithography printers, nano-imprint lithography systems, reticle cleaning tools, reticle inspection and metrology tools, reticle stockers, reticle storage containers, and equipment for transporting reticles from tool to tool within a manufacturing factory. Under current practice, reticle transfer and placement equipment is seldom cleaned, despite the tendency of these components to accumulate debris such as contamination and particulates. Since micrographic printers are among the most expensive production tools for fabricating integrated circuits, it is desirable to minimize non-essential maintenance activities on these tools, especially when such maintenance may potentially cause other problems to these bottleneck tools.

Individual semiconductor (integrated circuit) devices are typically produced by creating multiple devices on a silicon wafer using well known semiconductor processing techniques including photolithography, deposition, and etching. The photolithographic processes are especially critical since they produce the design patterns responsible for integrated circuit functionally. Moreover, various types of photolithographic processes are repeated multiple times in the production of complex integrated circuits. For example, certain circuits may require as many as forty or more pattern levels.

### SUMMARY OF THE INVENTION

This invention describes a new cleaning device and a new cleaning technique to enable the automatic removal of contamination and particulates from the reticle transfer arm(s) and positioning/support interface of a reticle handling tool without opening the tool. In this technique, a cleaning device may include a cleaning pad comprising an elastometer material that conforms around and traps particles or contamination residing on a contaminated surface when the cleaning pad contacts the contaminated surface. For purposes of this invention, the elastometer may be referred to as a “conform and trap material.” In this application, the term “conform and trap material” should be understood to mean the same concept as described by the term ‘tacky material’ in the provisional U.S. patent application filing No. 61/617,464 having filing date Mar. 29, 2012. The cleaning device, which may include a conform and trap material, is transferred into the reticle handling tool, transported through the reticle handling tool in the same manner and along the same path as a reticle, contacted against surfaces that a reticle touches, and transferred out of the reticle handling tool.

The cleaning device consists of a cleaning pad, comprised of a conform and trap material, secured to the base substrate, the cleaning pad having a desired density, elasticity, hardness, particle or contamination conformity, and particle or contamination trapping ability that cause the cleaning pad to remove contamination and particulates from the reticle transfer and placement equipment when the cleaning device contacts robot transfer arm(s) and reticle positioning/support interface.

When the cleaning device is grasped by the robot arm(s) using a vacuum, contamination on the arm(s) is removed from the arm(s) and embedded at or in the surface of the elastometer material. Such contamination is effectively held in place by the elastomer material. Similarly, when the cleaning device is positioned at the reticle plane of the reticle handling tool by robot arm(s) and held securely by means of vacuum applied to the reticle positioning/support interface, contamination on the positioning/support interface is removed from the interface and embedded at or in the surface of the elastometer. Such contamination is effectively held in place by the elastometer. After the cleaning device is removed from the printer, the contact and trap material may be cleaned to remove contamination. In one method of cleaning, a sacrificial film, referred to as flexible contamination removal film, may be applied to the cleaning device surface and then peeled away, effectively removing the contamination from the device surface. In this application, the term “flexible contamination removal film” should be understood to mean the same concept as described by the term ‘flexible contamination removal tacky film’ in the provisional application

### BRIEF DESCRIPTION OF THE DRAWINGS

FIG. 1 is a view of a micrographic scanner/stepper printer that may include the cleaning device in accordance with the invention;

FIG. 2 is a diagram of a reticle for a micrographic printer in accordance with the invention;

FIG. 3A is a diagram of a cleaning device in accordance with the invention;

FIG. 3B is a diagram of a cleaning device with a roughened surface in accordance with the invention;

FIG. 4 is a diagram of the reticle transfer robot arm in accordance with the invention;

FIG. 5A is a diagram of the reticle positioning/support interface and cleaning device inside the printer in accordance with the invention;

FIG. 5B is a diagram of the reticle positioning/support interface and cleaning device inside the printer in which the cleaning pad covers only the surface region of the cleaning device that contacts the surface region of the reticle positioning/support interfaces that actually touches a reticle, in accordance with the invention;

FIG. 6A-6C are diagrams showing how a cleaning device is operable to remove contamination and particulates from a reticle positioning/support interface inside the printer in accordance with the invention;

FIG. 7 is a diagram illustrating a second embodiment of the cleaning device in which vacuum grooves and outer upper side surfaces of printer transfer and support elements are cleaned in accordance with the invention;

FIG. 8A-8B are diagrams showing one method for removing contamination from the surface of the cleaning device;

FIG. 9 is a flowchart illustrating a method for cleaning the reticle transfer robot arm(s) and reticle positioning/support interface in reticle handling and placement equipment in accordance with the invention;

FIG. 10 is a flowchart illustrating a method for removing contamination and particles from the cleaning device in accordance with the invention;

### DETAILED DESCRIPTION OF PREFERRED EMBODIMENTS

Integrated circuit manufacturing may benefit by providing a quick and simple method for automatically cleaning the robot transfer arm(s) and the reticle positioning/support interface of reticle transfer and placement equipment in order to remove contamination and particulates which may migrate from the transfer and support components onto the area of the reticle containing the circuit pattern where it may block incident light from replicating the designed pattern features, resulting in non-functional electrical circuits. Similarly, integrated circuit manufacturing may also benefit by providing an automatic method for cleaning reticle transfer and positioning/support components in order to remove contamination and particulates that may cause the reticle to be lifted up at one or more edges into a position not perpendicular to the incident beam in the printer, a condition that also produces non-functional electrical circuits. In addition, since the reticle is typically stepped over many areas of the wafer during the printing operation, the presence of contamination in one or more positions on the reticle or non-optimal positioning of the reticle results in the production of many non-functional devices on each wafer, leading to serious yield loss and unacceptably high product cost.

This invention relates generally to a cleaning device for cleaning the handling and support interface for a reticle inside a reticle handling tool, such as, for example, a micrographic scanner/stepper printer. The handling and support components are generally referred to as a robot transfer arm(s) and a reticle positioning/support interface, which are used to move the reticle into to printer and position it at the desired location within the printer. The invention will be described in the embodiment of a micrographic scanner/stepper printer, but as will be appreciated by a person skilled in the art, the cleaning device and method may also be used with other types of reticle handling tools, such as, for example, micrographic optical scanner/stepper printers, immersion scanners, deep ultraviolet (deep UV) and extreme ultraviolet (EUV) lithography printers, nano-imprint lithography systems, reticle cleaning tools, reticle inspection and metrology tools, reticle stockers, reticle storage containers, and equipment for transporting reticles from tool to tool within a manufacturing factory.

It is desirable to provide a device for cleaning the transfer and support interfaces for a reticle inside a micrographic scanner/stepper printer and a method to perform the cleaning so that the robot transfer arm(s) and reticle positioning/support interface inside the printer may be cleaned more rapidly and effectively without resorting to taking the printer off-line for maintenance, and it is to this end that the present invention is directed.

This invention describes a new cleaning device and a new cleaning technique to enable the automatic removal of contamination and particulates from the reticle transfer arm(s) and positioning/support interface of a reticle handling tool without opening the tool. In this technique, a cleaning device may include a cleaning pad comprising an elastometer material that conforms around and traps particles or contamination residing on a contaminated surface when the cleaning pad contacts the contaminated surface. For purposes of this invention, the elastometer may be referred to as a “conform and trap material.” In this application, the term “conform and trap material” should be understood to mean the same concept as described by the term ‘tacky material’ in the provisional U.S. patent application filing No. 61/617,464 having filing date Mar. 29, 2012. The cleaning device, which may include a conform and trap material, is transferred into the reticle handling tool, transported through the reticle handling tool in the same manner and along the same path as a reticle, contacted against surfaces that a reticle touches, and transferred out of the reticle handling tool. The cleaning device may have approximately the same form factor of a reticle, where the term form factor is generally understood to mean size and shape. Alternatively, the cleaning device may have approximately the same form factor as a reticle with an attached pellicle. In another embodiment, the cleaning device may have the approximate form factor as a reticle and pellicle but may have slight modifications in size or weight such that it touches areas of the reticle transfer and placement equipment that the reticle does not touch by being, for example, slightly larger than the reticle. In another embodiment, the cleaning device may have the approximate form factor as a reticle with attached pellicle but may have slight modifications in size or weight such that it touches areas of the reticle transfer and placement equipment that the reticle does not touch. In another embodiment, the cleaning device may have the identical weight as a reticle. In another embodiment, the cleaning device may have the identical weight as a reticle with an attached pellicle. In another embodiment, the cleaning device may have the approximate weight of a reticle but may be optimized, for example by increasing the weight, to enhance the ability of the cleaning pad to attract and retain contamination and particulates or by decreasing the weight to take advantage of other means of attracting and retaining the contamination and particulates. In another embodiment, the cleaning device may have the approximate weight of a reticle with an attached pellicle but may be optimized, for example by increasing the weight, to enhance the ability of the cleaning pad to attract and retain contamination and particulates or by decreasing the weight to take advantage of other means of attracting and retaining the contamination and particulates. In another embodiment, the cleaning device may have a corrugated or roughened surface in areas that contact the reticle, the surface height peak-to-valley distances being approximately in the range of 0.1-5 mils and the lateral surface pitch having a periodicity approximately in the range of 0.05-5 mm. In yet another embodiment, the cleaning device may have a corrugated surface whose surface spatial variation, such as surface height peak-to-valley distances and lateral surface variation, may not be spatially periodic in areas that contact the reticle, the surface height peak-to-valley distances being approximately in the range of 0.1-5 mils and the lateral surface planar variation being approximately in the range of 0.05-5 mm.

The cleaning device consists of a cleaning pad, comprised of a conform and trap material, secured to the base substrate, the cleaning pad having a desired density, elasticity, hardness, particle or contamination conformity, and particle or contamination trapping ability that cause the cleaning pad to remove contamination and particulates from the reticle transfer and placement equipment when the cleaning device contacts robot transfer arm(s) and reticle positioning/support interface. In the preferred embodiment, the cleaning pad may completely cover the entire surface of the cleaning device such that it may contact all surfaces of reticle transfer and placement equipment that normally contact a reticle. In another embodiment, however, the cleaning pad may cover only one or more surfaces of the cleaning device, especially in the situation wherein not every surface to a reticle contacts a surface of reticle transfer and placement equipment. In yet another embodiment, the cleaning pad may not completely cover the entire area of a cleaning device, as long as it covers all of the surfaces where a reticle contacts transfer and placement equipment.

When the cleaning device is grasped by the robot arm(s) using a vacuum, contamination on the arm(s) is removed from the arm(s) and embedded at or in the surface of the elastometer material. Such contamination is effectively held in place by the elastomer material. Similarly, when the cleaning device is positioned at the reticle plane of the reticle handling tool by robot arm(s) and held securely by means of vacuum applied to the reticle positioning/support interface, contamination on the positioning/support interface is removed from the interface and embedded at or in the surface of the elastometer. Such contamination is effectively held in place by the elastometer. After the cleaning device is removed from the printer, the contact and trap material may be cleaned to remove contamination. In one method of cleaning, a sacrificial film, referred to as flexible contamination removal film, may be applied to the cleaning device surface and then peeled away, effectively removing the contamination from the device surface. In this application, the term “flexible contamination removal film” should be understood to mean the same concept as described by the term ‘flexible contamination removal tacky film’ in the provisional application.

In accordance with the invention, a cleaning device is provided that will clean the reticle transfer arm(s) and positioning/support interface of a micrographic printer without opening the printer chamber for maintenance. In particular, the cleaning device may be placed within the printer in a manner similar to the manner of inserting a reticle during normal usage wherein one or more surface(s) of the cleaning device contacts the reticle transfer arm(s) and positioning/support interface of the printer to remove contamination and particulates. In a preferred embodiment, the cleaning device that may be shaped like a typical semiconductor reticle that typically fits into the printer. The cleaning device may also be a ceramic plate or any type of substrate, which may fit into the printer at the position normally occupied by the reticle. The contact and trap material comprising the cleaning device surface may have predetermined mechanical and/or chemical characteristics, such as density, elasticity, hardness, conformity to particles, trapping capability for particles, planarity, abrasiveness, and/or chemical properties so that when the cleaning device contacts the surface(s) of the reticle transfer arm(s) and positioning/support interfaces, the transfer arm(s) and interfaces may be cleaned and the contamination and particulates may be removed. In a preferred embodiment, the cleaning device may be a semiconductor reticle, ceramic, or any material to which the cleaning pad will attach.

In accordance with another aspect of the invention, the method further comprises contacting the printer arm(s) and interfaces with the cleaning device at periodic intervals so that contamination and particulates are removed from the arm(s) and interface elements.

In accordance with another aspect of the invention, a method for cleaning the reticle transfer arm(s) and positioning/support interfaces in a micrographic printer is provided wherein the method comprises loading a cleaning device into the printer, the cleaning device having approximately the same configuration as the reticles normally used to print patterns on semiconductor wafers and the cleaning device having a surface with predetermined properties, such as density, elasticity, hardness, conformity to particles and contamination, abrasiveness, that allow the elastometer to penetrate to a depth greater than about 0.5 mm into the vacuum port holes in the reticle transfer arm(s) and positioning/support interface and or may penetrate a distance of about 0.5-5 mm around the upper side surfaces of arm and interface outer upper edges to clean the contamination and particulates from inside the top edge of the vacuum holes and from arm and interface edges.

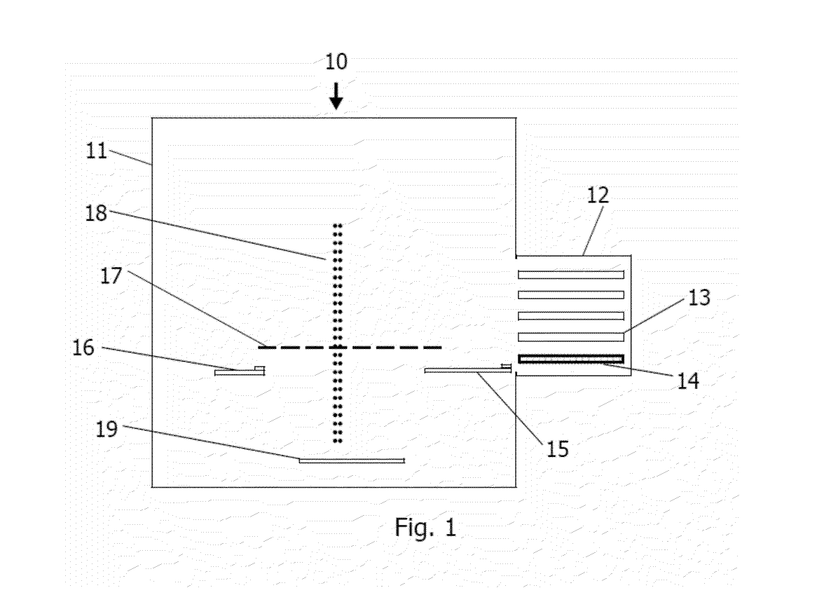

FIG. 1 is a stylized diagram illustrating a micrographic scanner/stepper printing system 10 that may be cleaned using the cleaning device in accordance with the invention. In particular, the system 10 may include a micrographic printer 11 connected to a reticle library station 12 that may contain a reticle(s) 13 for use in printing patterns for semiconductor integrated circuits. Alternatively, reticle library 12 may contain a cleaning device 14 shaped like a typical semiconductor reticle. Printer 11 may further include a robot transfer arm(s) 15 which is used to move reticles from reticle library 12 into the main body of printer 11 and a reticle positioning/support interface 16 for positioning the reticle in the reticle plane 17 of printer 11 at an appropriate location in the path of optical beam 18 that exposes patterns in photoresist or other material on a semiconductor wafer 19 to form integrated circuits. Instead of the current procedure for cleaning arm(s) 15 and positioning/support interface 16 in which printer 11 is taken out of production and opened to provide access to the arm(s) 15 and positioning/support interface 16, the cleaning device 14 in accordance with the invention permits the transfer arm(s) 15 and positioning/support interfaces 16 to be cleaned without opening the printer. In particular, the cleaning device may be introduced periodically into the reticle library in accordance with the invention and moved through the printer in accordance with the invention. Thus the cleaning device will clean the transfer arm(s) and positioning/support interfaces when instigated during normal operation of the printer without opening the printer.

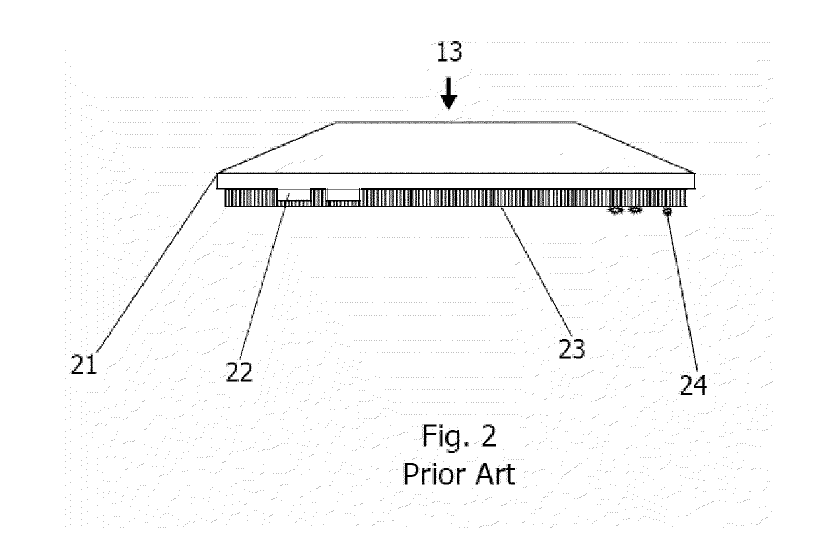

FIG. 2 is a stylized diagram of a photolithographic reticle 13 according to the prior art. Reticle 13 consists of a base substrate 21 containing metallized patterns 22 used to create the integrated circuit in semiconductor wafer 19. The side of reticle 13 containing patterns 22 may be covered by a pellicle 23 that is a thin transparent film whose outer surface is far enough away from patterns 22 so that moderate-to-small sized particulates 24 that land on the pellicle will be too far out-of-focus to print on semiconductor wafer 19. However, larger sized contamination and particulates may interfere with the integrity of the printing process either by blocking light required to form designed patterns on wafer 19 or by elevating one or more edges of the reticle 13 to a position not perpendicular to the printing beam 18 such that the pattern is out-of-focus.

Now the cleaning device and cleaning medium in accordance with the invention will be described in more detail.

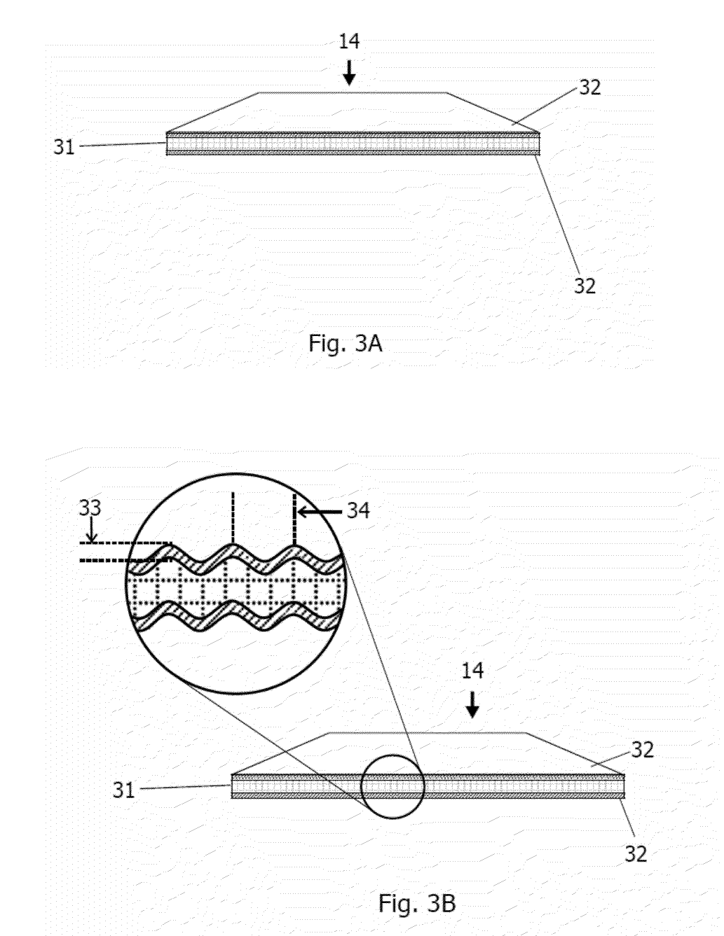

FIG. 3A is a stylized diagram illustrating a cleaning device 14 in accordance with the invention. Cleaning device 14 may include a base substrate 31 and one or more cleaning pad(s) 32 mounted on the substrate. The substrate may be any material that may support the cleaning pad and has sufficient strength to resist breaking when transferred into and out of the printer. Thus, the substrate may be plastic, metal, glass, silicon, ceramic or any other similar material. In a preferred embodiment, the substrate 31 may have substantially the same form factor as a reticle. The cleaning pad may be generally between 0.5 and 20 mils thick

In accordance with another aspect of the invention, a method for cleaning the reticle transfer arm(s) and positioning/support interfaces in a micrographic printer is provided wherein the method comprises loading a cleaning device into the printer, the cleaning device having the same configuration as the reticles normally used to print patterns on semiconductor wafers and the cleaning device having a surface covered by a elastomeric contact and trap material with predetermined properties, such as density, elasticity, hardness, particle or contamination conformity, and particle or contamination trapping ability, or abrasiveness, that clean the arm(s) and interfaces. For example, the elasticity and particle conformity of the contact and trap material may be sufficient to attract and retain contamination and particulates in the size range of 0.01 to 100 microns by adhesive or electrostatic transfer. Alternatively, the elasticity and particle conformity of the cleaning pad may be comparable to the elasticity and particle conformity of silicon polymer particle cleaning materials available from International Test Solutions, Inc. Additionally, the elasticity and particle conformity of the cleaning pad may be sufficiently low to avoid problems in handling the cleaning device as it moves through the reticle transfer and placement equipment. The elasticity and particle conformity of the cleaning pad may be sufficient that contamination and particulates adhere to the cleaning pad when the cleaning pad is contacted against transfer arm(s) and positioning/support interfaces and not released into the environment. In order to avoid compromising the functionally of both micrographic printers and reticles, the cleaning device may have a low outgassing rate under NASA standard testing outlined in ASTM E595 wherein its total weight loss may be less than or equal to 0.05% and its total collected volatile condensable materials (CVCM) may be less than or equal to 0.1%. The cleaning device may also exhibit low material transference of silicone below 0.05 atomic %, as measured using X-ray Photoelectron Spectroscopy (ESCA/XPS) at 150 C for 60 minutes, such as done by the Evans Analytical Group.

In a preferred embodiment, cleaning pad 32 may completely cover the top and bottom surfaces of base substrate 31 so that it may contact a variety of styles of robot transfer arm(s) 15 and reticle positioning/support interfaces 16 that may be encountered using micrographic printers made by different vendors. Alternatively, cleaning pad 32 may cover only the bottom surface of cleaning device 14 if the cleaning device is dedicated to a specific model of micrographic printer that grasps reticles only at the bottom. In another embodiment, cleaning pad 32 may not necessarily cover the entire surface of cleaning device 14 but instead may cover one or more surfaces of cleaning device 14 that contact one or more surfaces of robot transfer arm(s) 15 and reticle positioning/support interfaces 16.

Cleaning pad 32 may be made of a conform and trap material with predetermined properties that contribute to the cleaning of the transfer arm(s) and positioning/support interface. For example, cleaning pad may have desired density, elasticity, hardness, particle or contamination conformity, and particle or contamination trapping ability that contribute to cleaning robot arm(s) 15 and support interfaces 16. The elasticity, particle conformity and particle trapping nature of cleaning pad may cause any contamination or particulates on the arms 15 and positioning/support interfaces 16 to preferentially stick to cleaning pad and therefore be removed from the transfer arm(s) and interface. In a preferred embodiment, cleaning pad comprises may be made of an elastomeric material comprising one or more rubbers, synthetic polymers, and natural polymers. The elastomeric material may have a predetermined elasticity, density, and surface tension parameters that allow the material to penetrate into the vacuum port holes and around the edges of the transfer arm(s) and positioning/support interface and remove the contamination and particulates, while retaining the integrity of the elastomeric matrix. In another embodiment, the elastomeric material may be a silicone polymer membrane with a thickness of the elastomeric material being generally between 0.5 and 20 mils thick, available for example from International Test Solutions, Inc.

As the cleaning device contacts one or more elements of the printer transfer arm(s) 15 of FIG. 1 and positioning/support interface 16 of FIG. 1 when it is moved by arm(s) 15 to positioning/support interface 16, the weight of the cleaning device and the applied vacuum exert a vertical contact force upon the cleaning device and arm(s) 15 and interface 16 whereby the contamination and particulates on the arm(s) and interface will be removed and retained by the cleaning pad material. The elasticity and particle conformity of the cleaning pad elastomer will remove the contamination and particulates from the arm(s) and interface but will not damage the arm(s) or interface.

FIG. 3B is a stylized diagram illustrating a cleaning device 14 in accordance with one aspect of the invention in which the surface of cleaning device 14 is roughened such as to exert tangential force on surface contamination and particles. The surface roughening may comprise a periodic pattern with the surface roughness having a peak-to-valley height amplitude 33 and a periodicity 34. The surface height peak-to-valley depths may be approximately in the range of 0.1-5 mils, and the lateral surface pitch may have a periodicity approximately in the range of 0.05-5 mm. Alternatively, the surface roughness may be spatially non-periodic with a surface height peak-to-valley depth in the range of 0.1-5 mils.

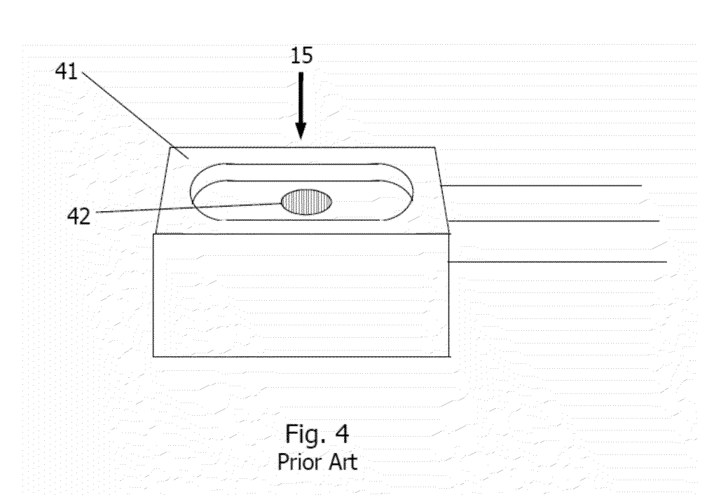

FIG. 4 is a stylized diagram of the reticle transfer robot arm(s) 15 in accordance with the invention;

Robot reticle transfer arm(s) 15 is used to grasp reticle 13 by contacting it with surface 41 and applying a vacuum through holes 42. After reticle 13 of FIG. 2 has been grasped, robot transfer arm(s) 15 removes it from reticle library station 12 and positions it onto reticle positioning/support interface 16 inside printer 11. Reticle transfer arm(s) 15 may also be used to transfer cleaning device 14 of FIG. 3A or FIG. 3B from reticle library station 12 to reticle positioning/support interface 16. As appreciated by a person skilled in the art, actual robot transfer arm configurations may differ among different printer vendors.

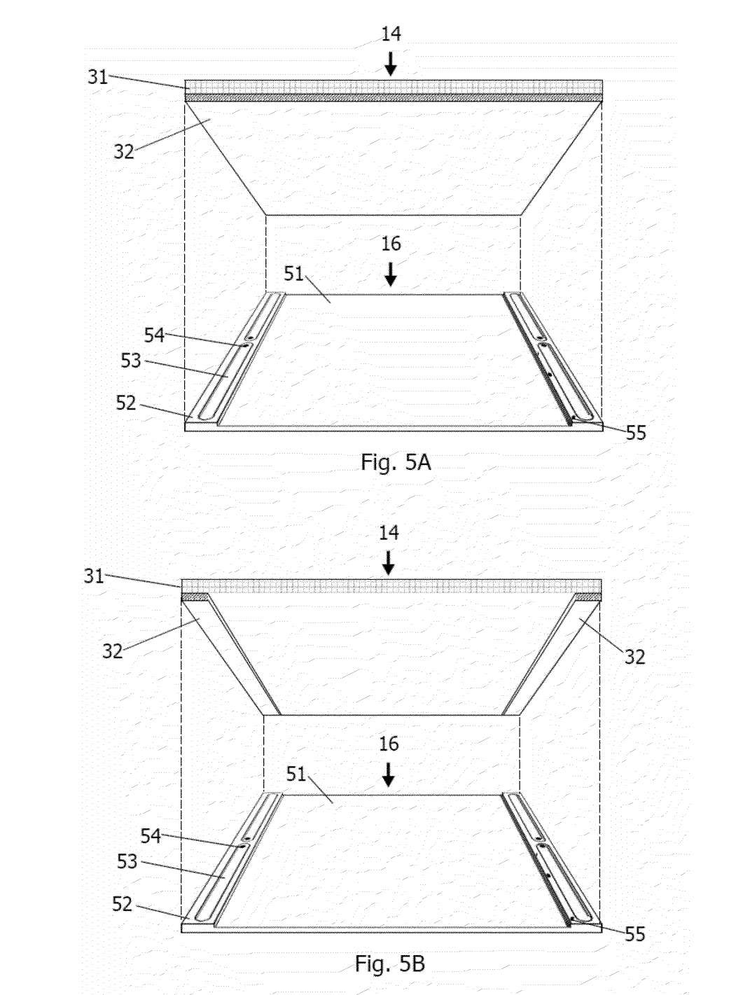

FIG. 5A is a stylized diagram showing the reticle positioning/support interface 16 and cleaning device 14 in accordance with the invention;

Reticle positioning/support interface 16 includes a base plate 51 with elevated regions 52 containing vacuum distribution grooves 53 that are used to grasp reticle 13 or cleaning device 14 by contacting it with the surface of elevated regions 52 and applying a vacuum in vacuum distribution grooves 53 through vacuum port hole(s) 54. Reticle positioning/support interface 16 may hold reticle 13 in place during photolithographic exposure which prints patterns to produce integrated circuits in a semiconductor wafer. As appreciated by a person skilled in the art, actual reticle positioning/support interface configurations may differ among different printer vendors. In accordance with this invention, reticle positioning/support interface 16 may also hold cleaning device 14 in contact against its top surfaces 52 so that cleaning pad 32 of cleaning device 14 may contact elevated regions 52 to remove contamination and particulates 55 from the top surface of elevated region 52.

FIG. 5B is a stylized diagram illustrating a cleaning device 14 in accordance with one aspect of the invention in which cleaning pad 32 may cover only the surface region of cleaning device 14 that contacts the surface region of robot transfer arm(s) 15 and/or reticle positioning/support interfaces 16 that actually touches reticle 13. As will be appreciated by a person skilled in the art, the contact area may be located on the bottom of cleaning device 14, the top of cleaning device 14, on both the top and bottom of cleaning device 14, or on one or modes sides of cleaning device 14, according to the specific physical configuration of the reticle handling robot transfer arm(s) 15 and reticle positioning/support interfaces 16 to be cleaned;

Now, a method for removing contamination and particulates from the robot transfer arm and positioning/support interface in accordance with the invention will be described.

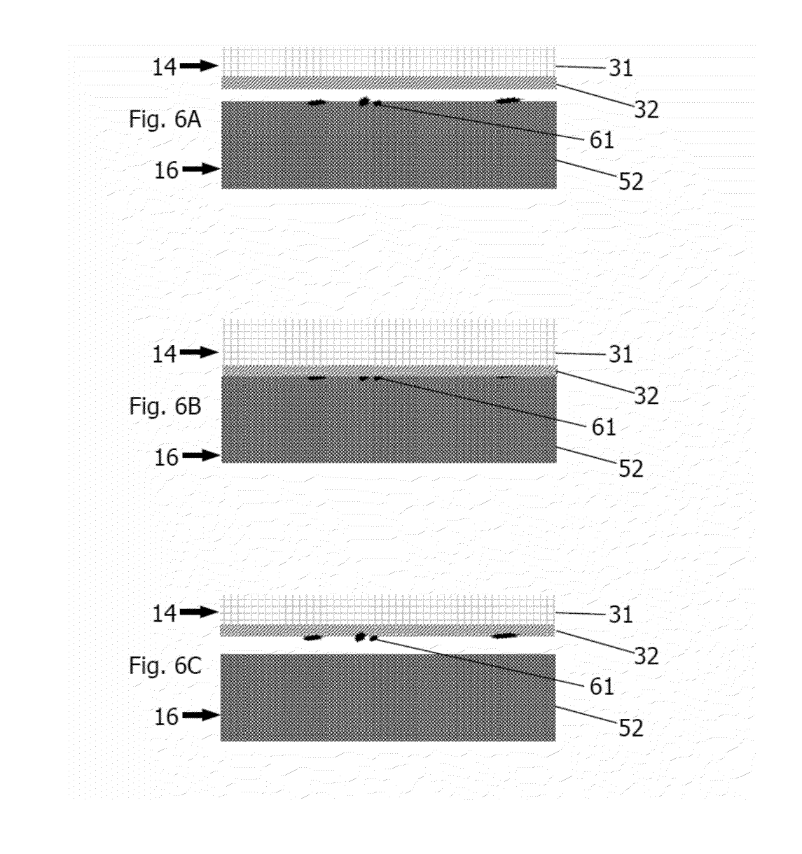

FIG. 6A through FIG. 6C show stylized diagrams explaining how cleaning device 14 is used to remove contamination and particulates from reticle positioning/support interface 16 in accordance with the invention;

FIG. 6A shows cleaning device 14 in close proximity to reticle positioning/support interface 16 immediately before the device 14 contacts the reticle interface 16. In this case, contamination or particulates 61 may be present on the top surface of elevated region 52 of reticle positioning/support interface 16.

FIG. 6B shows cleaning device 14 positioned above reticle positioning/support interface 16 after device 14 has been loaded onto reticle interface 16 and pulled against the interface by a vacuum. During the period of contact, contamination or particulates 61 may be dislodged from the top surface of elevated region 52 of reticle positioning/support interface 16 and attracted to the outer surface of cleaning device 14 because of the absorbency of the elastometer of cleaning pad 32.

FIG. 6C shows cleaning device 14 positioned above reticle positioning/support interface 16 immediately after the vacuum has been released in vacuum distribution grooves 53 and device 14 has been raised to a position slightly above reticle interface 16. At this point, contamination or particulates 61 may be transferred to the elastometer of cleaning pad 32 on the surface of cleaning device 14, so that they may be removed from printer 10 when cleaning device 14 is removed from reticle library 12.

As will be appreciated by a person skilled in the art, the same principles governing removal of contamination and particulates from the reticle positioning/support interface 16 apply to the removal of contamination and particulates from robot transfer arm(s) 15.

Now, a method for removing contamination and particulates from the cleaning device in accordance with the invention will be described.

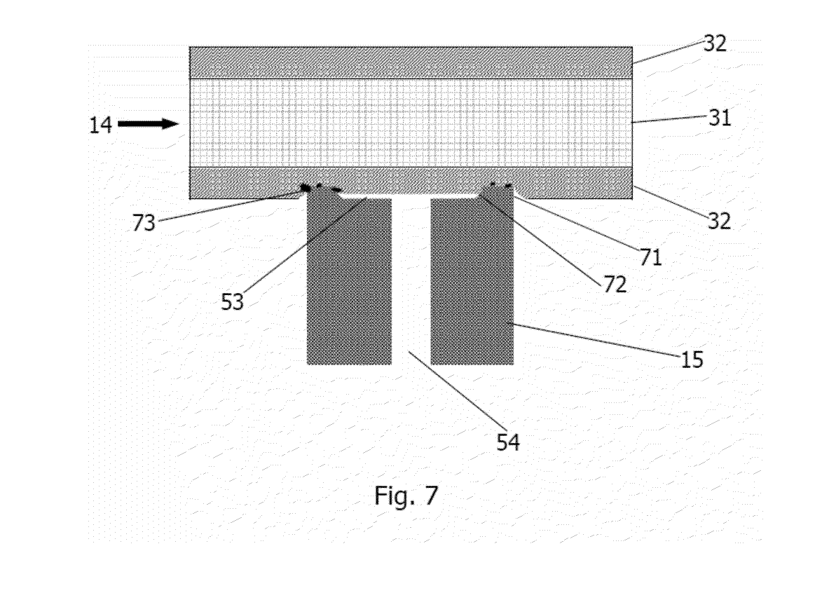

FIG. 7 is a side view illustrating a second embodiment of the cleaning device 14 in accordance with the invention. In more detail, the cleaning device 14 may include a cleaning pad 32 comprised of one or more different layers of material which may penetrate a distance of about 0.5-5 mm into the vacuum distribution grooves 53, especially near edge 72 of grooves 53, may penetrate to a depth greater than about 0.5 mm into the vacuum port holes 54 in the reticle transfer arm(s) 15 and positioning/support interface (16) and/or may penetrate and wrap along the outer upper side edge surfaces(s) 71 of reticle positioning/support interface 16 in order to remove contamination and particulates 73 from inside the vacuum distribution grooves 53, inside the vacuum hole ports 54, or along the outer upper side edge surfaces 71 of the positioning/support interface.

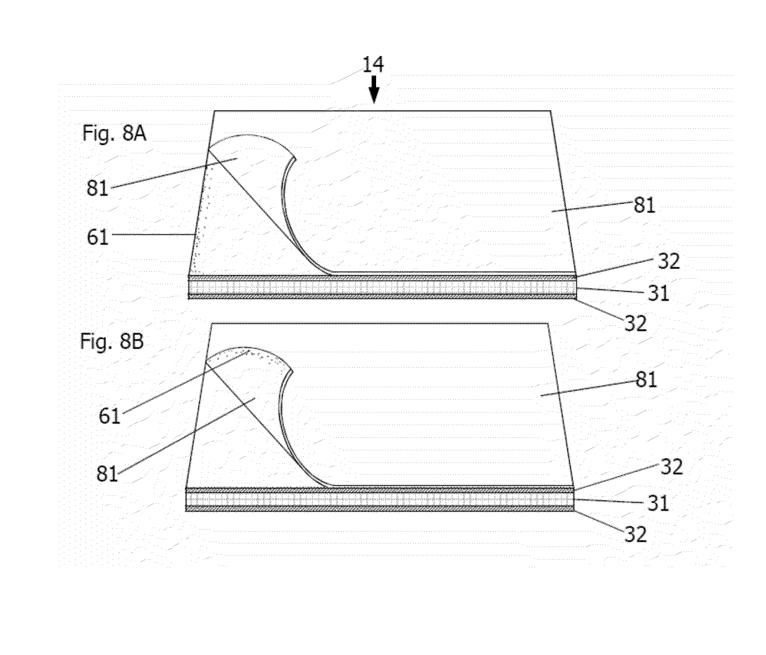

FIG. 8A and FIG. 8B are stylized diagrams of a cleaning device showing one method for removing contamination and particulates from the surface of the cleaning device in accordance with the invention. The cleaning medium consists of a flexible contamination removal film 81 that covers at least the entire surface area of robot reticle transfer arm(s) 15 and reticle positioning/support interface 16 that contact the reticle during transport into, within, and out of the reticle handling tool. Flexible contamination removal film 81 is applied to the device and used for one or more cleaning operations before being replaced, as will be described.

FIG. 8A shows cleaning device 14 after it is removed from reticle library station 12. Contamination and particulates 61 may be present on the surface of cleaning pad 32 as a result of the previous cleaning of robot transfer arm(s) 15 and reticle positioning/support interface(s) 16. FIG. 8A also shows a flexible contamination removal film 81 in the process of being applied to the surface of cleaning device 14 in accordance with the invention to remove contamination and particulates 61 from cleaning pad 32 of device 14, leaving a surface that is substantially free from contamination and particulates. In the preferred embodiment, flexible contamination removal film 81 may be pressed the entire surface area of cleaning device 14 to clean the entire area of cleaning pad 32. In another embodiment, flexible contamination removal film 81 may be pressed against the portion of surface area of cleaning device 14 that contacts surfaces of the robot transfer arm(s) 15 and reticle positioning/support interface 16 that touch reticles.

As will be appreciated by a person skilled in the art, flexible contamination removal film 81 needs to have a higher degree of conformation and trapping of particles and contamination than cleaning pad 32 so that it removes contamination from cleaning pad 32 but not be so adhesive that it causes the cleaning pad 32 to delaminate from base substrate 31 of cleaning device 14.

FIG. 8B shows cleaning device 14 after the flexible contamination removal film 81 has been pressed against the entire surface area of cleaning device 14 and then partially removed by peeling. At this point, contamination and particulates 61 may be transferred from the surface of cleaning pad 32 to the flexible contamination removal film 81 leaving a cleaning pad surface 32 that is substantially free from contamination and particulates. After the flexible contamination removal material is completely removed from cleaning device 14, it may be disposed of outside the clean manufacturing environment so that contamination and particulates do not further affect the integrated circuit manufacturing process. In accordance with this invention, cleaning device 14 may then be reinserted into reticle library 12 for cleaning additional printer robot transfer arm(s) (15) and reticle positioning/support interfaces (16). Reinsertion of device 14 into library 12 may be done by a variety of methods, such as for example via reticle cassettes, SMIF pods, or by means of the standard method for loading reticles into the reticle library used in a particular factory.

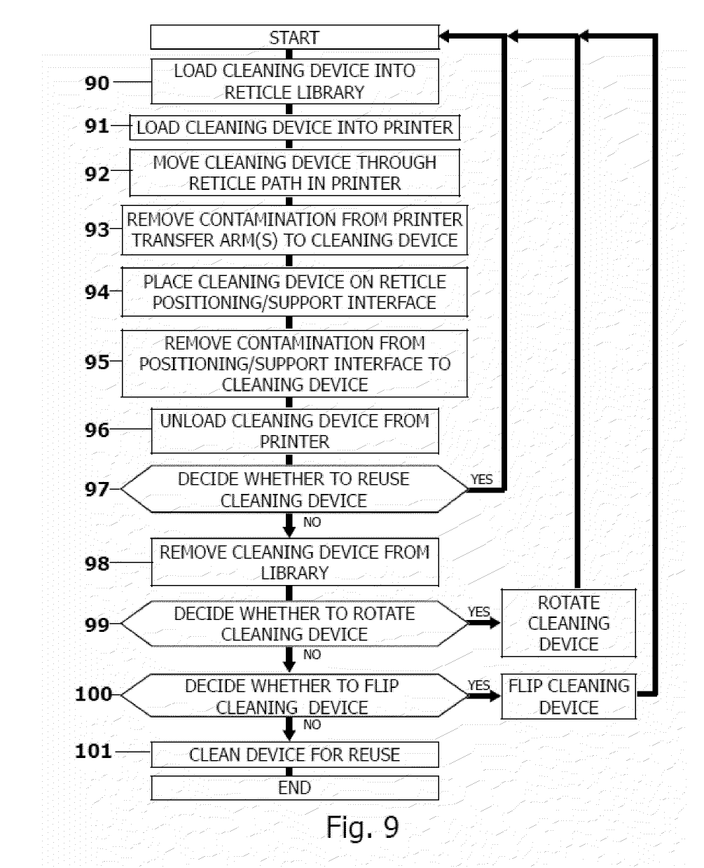

FIG. 9 is a flowchart illustrating a method for cleaning the reticle transfer robot arm(s) 15 and reticle positioning/support interface 16 of a micrographic scanner/stepper printer in accordance with the invention. As will be appreciated by a person skilled in the art, the specific illustration in which cleaning device 14 removes contamination and particles 55 from robot transfer arm(s) 15 and reticle positioning/support interface 16 in a micrographic printer 10 is representative of the more general application in which the cleaning device and cleaning method may be used to remove contamination and particles 55 from any reticle transfer and placement equipment.

In particular, in step 90, cleaning device 14 is loaded into the reticle library 12 of a micrographic scanner/stepper printer 10. In step 91, cleaning device 14 is loaded by printer robot transfer arm(s) 15 into printer 10. In step 92, cleaning device 14 is moved through the reticle path in printer 10 in the same manner and along the same path as reticle 13 so that it touches and cleans surfaces that a reticle touches. In step 93, contamination and particles 55 are removed from robot arm(s) 15 and transferred to cleaning device 14. In step 94, cleaning device 14 is placed on reticle positioning/support interface 16. In step 95, contamination and particles 55 are removed from reticle positioning/support interface 16 and transferred to cleaning device 14. In step 96, cleaning device 14 is unloaded from printer 10 and placed in reticle library 12. In step 97, a decision is made as to whether cleaning device 14 may be reused in its current orientation. If reuse without reorientation is selected, the wafer remains inside reticle library 12 until the next cleaning operation. If in step 97 the decision is made to discontinue use of cleaning device 14 in its current orientation, then in step 98, cleaning device 14 is removed from reticle library 12. In step 99, a decision is made as to whether cleaning device 14 may be rotated to expose a clean surface of cleaning pad 32. Similarly, in step 100, a decision is made as to whether cleaning device 14 may be flipped over to expose a clean surface of cleaning pad 32. As will be appreciated by a person skilled in the art of photolithography, the decision to reuse a cleaning device depends on the specific configuration of robot transfer arm(s) and reticle positioning/support interface 16 associated with the specific manufacturer or model of printer. For example, if the robot transfer arm(s) 15 and reticle positioning/support interface 16 contact the cleaning device only on the bottom surface but not on the top surface and if this contact occurs along two of the four outer edges but not all four outer edges of the cleaning device, then cleaning device 14 may be used four times before cleaning its cleaning pad. In this case the cleaning pad may be used once, rotated 90 degrees for a second usage, flipped upside down for a third usage, rotated 90 degrees for a fourth usage, and then cleaned. On the other hand, if the robot transfer arm(s) 15 and reticle positioning/support interface 16 contact the cleaning device on both its top and bottom surfaces, then cleaning device 14 may be used only two times before cleaning its cleaning pad. In this case, the cleaning pad may be used once and then rotated 90 degrees for a second usage, and then cleaned. In step 99, if a decision is made to rotate and reuse cleaning device 14, the device is reinserted into reticle library 12 with the appropriate geometric orientation. Likewise in step 100, if a decision is made to flip and reuse cleaning device 14, the device is reinserted into reticle library 12 after being flipped upside down. If a decision is made to not reuse cleaning device 14, cleaning pad 32 of cleaning device 14 is cleaned using a flexible contamination removal film 81 according to step 101, after which cleaning device 14 is ready for reuse.

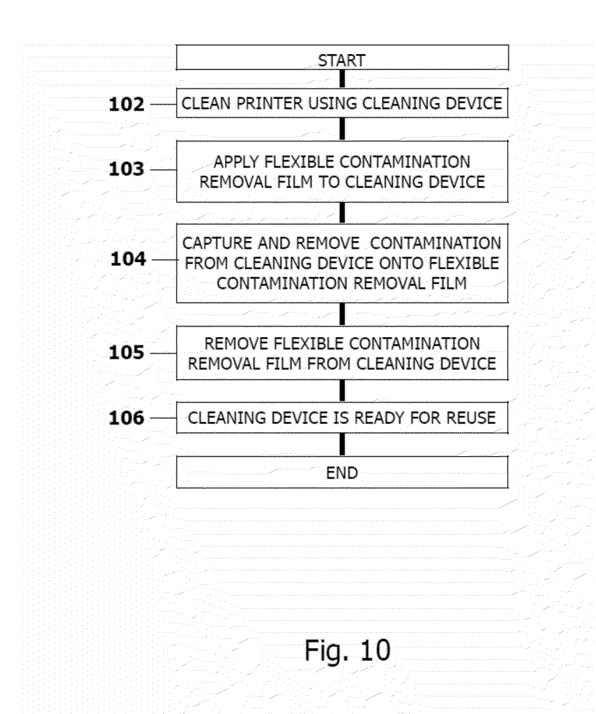

FIG. 10 is a flowchart illustrating a method for removing contamination and particles from cleaning device 14. In particular, in step 103, a flexible contamination removal film is applied to one or more surfaces of cleaning device 14 after cleaning device 14 has been used to clean printer 10 and removed from reticle library 12 in step 102. Flexible contamination removal film is applied to cover at least a portion of the surface area of said cleaning device that contacts said surfaces of said reticle transfer and placement equipment that touch reticles. In step 104, contamination and particles 61 are removed from cleaning pad 32 of cleaning device 14 onto flexible contamination removal film 81. In step 105, flexible contamination removal film 81 is peeled away from cleaning device 14 with the contamination and particles 61 adhering to the film 81. In step 106, the cleaning device is ready for reloading into reticle library for reuse.

While the foregoing has been with reference to a particular embodiment of the invention, it will be appreciated by those skilled in the art that changes in this embodiment may be made without departing from the principles and spirit of the invention, the scope of which is defined by the appended claims.

What is claimed is:

1. A cleaning device for cleaning reticle transfer and placement equipment, comprising:
a base substrate, said base substrate having approximately a form factor of a reticle used by said reticle transfer and placement equipment; and
a cleaning pad attached to said base substrate, said cleaning pad having at least one of a density, an elasticity, a hardness, a particle conformity, a contamination conformity, a particle trapping ability, and a contamination trapping ability such that at least one of said contamination and said particles on said reticle transfer/placement equipment are transferred to said cleaning pad when said cleaning device is contacted by said reticle transfer and placement equipment.

2. The cleaning device of claim 1, wherein said cleaning device has the identical form factor as said reticle.

3. The cleaning device of claim 1, wherein said cleaning device has the identical form factor as said reticle with an attached pellicle.

4. The cleaning device of claim 1, wherein said cleaning device has slight modifications in at least one of size and weight such that it touches areas of said reticle transfer and placement equipment that said reticle does not touch.

5. The cleaning device of claim 1, wherein said cleaning device has a weight greater than the weight of said reticle.

6. The cleaning device of claim 1, wherein said cleaning device has a weight less than the weight of said reticle.

7. The cleaning device of claim 1, wherein said cleaning device has a corrugated surface in areas that contact said reticle, the surface height peak-to-valley depths being approximately in the range of 0.1-5 mils and the lateral surface pitch having a periodicity approximately in the range of 0.05-5 mm.

8. The cleaning device of claim 1, wherein said cleaning device has a corrugated surface whose surface spatial variation, such as surface height peak-to-valley distances and lateral surface variation, are not spatially periodic in areas that contact said reticle, the surface height peak-to-valley distances being approximately in the range of 0.1-5 mils and the lateral surface planar variation being approximately in the range of 0.05-5 mm.

9. The cleaning device of claim 1 wherein said cleaning pad is approximately between 0.5 and 20 mils thick.

10. The cleaning device of claim 1 wherein said cleaning pad completely covers an entire surface of said cleaning device.

11. The cleaning device of claim 1 wherein said cleaning pad covers at least one surface region of said cleaning device that contacts at least one surface region of said transfer and placement equipment that touch reticles in said reticle handling tool.

12. The cleaning device of claim 1, wherein at least one of said density, said elasticity, said hardness, said particle conformity, said contamination conformity, said particle trapping ability, and said contamination trapping ability of said cleaning pad is sufficient to attract and retain said contamination and said particulates in the size range of 0.01 to 100 microns by at least one of adhesive and electrostatic transfer.

13. The cleaning device of claim 1 wherein said cleaning pad is composed of a silicon polymer material approximately between 0.5 and 20 mils thick.

14. The cleaning device of claim 1, wherein said at least one of said density, said elasticity, said hardness, said particle conformity, said contamination conformity, said particle trapping ability, and said contamination trapping ability of said cleaning pad is sufficiently low to avoid problems in handling said device as it moves through said reticle transfer and placement equipment.

15. The cleaning device of claim 1, wherein said cleaning device has a low outgassing rate under NASA standard testing outlined in ASTM E595 wherein a total weight loss may be less than or equal to 0.05% and a total collected volatile condensable materials (CVCM) may be less than or equal to 0.1%.

16. The cleaning device of claim 1, wherein said cleaning device has a low rate of material transference of silicone below 0.05 atomic %, as measured using X-ray Photoelectron Spectroscopy (ESCA/XPS) at 150 C for 60 minutes.

17. The cleaning device of claim 1, wherein said cleaning pad comprises may be made of an elastomeric material comprising at least one of the group rubbers, synthetic polymers, and natural polymers

18. A method for cleaning reticle transfer and placement equipment in a reticle handling tool, the method comprising:
introducing a cleaning device into said reticle handling tool without opening said reticle handling tool, wherein said cleaning device is approximately the same shape and size of a reticle;
transporting said cleaning device through said reticle handling tool in a same manner and along a same path as a reticle; and
cleaning surfaces that said reticle touches, said cleaning device comprising a cleaning pad, secured to a base substrate, said cleaning pad having predetermined characteristics that cause said cleaning pad to remove said contamination and said particulates from said reticle transfer and placement equipment when said cleaning device contacts said robot transfer arm(s) and said reticle positioning/support interface.

19. The method of claim 18, wherein said cleaning pad comprises an elastomeric material that traps and removes said contamination and particulates from said robot transfer arm(s) and reticle positioning/support interface onto said surface of the cleaning pad.

20. The method of claim 18, wherein said transfer and placement equipment comprises at least one of the group vacuum distribution grooves, vacuum port holes, and transfer arms, interface support outer upper side edge surfaces and wherein said elastomeric material may penetrate a distance of greater than about 0.5 mm into at least one of the group said vacuum distribution groove(s), said vacuum port holes, and said outer upper side edge surfaces of said arm and said interface support.
